(19) United States
(12) Patent Application Publication
(10) Pub. No.: US 2025/0006497 A1
(43) Pub. Date: Jan. 2, 2025

(54) MOSFET DEVICE AND MANUFACTURING METHOD THEREFOR

(71) Applicant: YUEZHOU SEMICONDUCTOR MANUFACTURING ELECTRONICS (SHAOXING) CORP, Shaoxing (CN)

(72) Inventors: Xiang LI, Shaoxing (CN); Zhiping XIE, Shaoxing (CN); Maojie CONG, Shaoxing (CN); Xinying LIANG, Shaoxing (CN); Yukai ZHANG, Shaoxing (CN)

(21) Appl. No.: 18/264,045

(22) PCT Filed: Mar. 20, 2023
(86) PCT No.: PCT/CN2023/082486

§ 371 Date: Aug. 2, 2023

(30) Foreign Application Priority Data
Oct. 24, 2022 (CN) 202211305002.2

(51) Int. Cl. H01L 21/04; H01L 29/16; H01L 29/66; H01L 29/78

(52) U.S. Cl. CPC H01L 21/0465; H01L 29/1608; H01L 29/66068; H01L 29/78

(57) ABSTRACT

A metal oxide semiconductor field effect transistor (MOSFET) device and a manufacturing method therefor. A first implantation region easy to diffuse and a second implantation region which is not easy to diffuse and has a deeper junction are formed in sequence. After ion implantation in a source region and the like is completed, the first implantation region is activated to form a required well region in a mode of junction diffusion in the first implantation region, and the second implantation region is used for increasing the depth of the well region, thereby avoiding the damage to the surface of a substrate at a channel and roughness of the surface of the channel of the device caused by the formation of a P well directly through multiple Al ion implantation. Besides, the ion implantation in the first and second implantation regions, and the source region can use a same mask layer.

### TECHNICAL FIELD

The present invention relates to the field of the manufacturing technology of MOSFET devices, in particular to a metal oxide semiconductor field effect transistor (MOSFET) device and a manufacturing method therefor.

### BACKGROUND

Silicon carbide (SiC) metal oxide semiconductor field effect transistor (MOSFET) devices have the advantages of high switching speed, low conduction resistance, and the like, can achieve a higher breakdown voltage level with a smaller drift layer thickness, can reduce the volume of power switch modules and reduce the energy consumption, and have obvious advantages in application fields such as power switches and converters.

Due to the weak diffusion of Al (aluminum) ion implantation in SiC, in an existing planar gate SiC MOSFET process, a certain depth of P well is usually obtained by multiple Al ion implantation first, and then, an N+source region, a P+bulk region (also known as a P+contact region), and the like are formed in the P well by ion implantation.

However, multiple Al ion implantation breaks the SiC surface at the planar gate SiC MOSFET channel, which leads to the roughness of the surface of the P well channel, increases the channel scattering, and limits the increase of the channel carrier mobility.

The above problems also exist in other planar MOSFET processes that use multiple Al ion implantation to form P wells.

### SUMMARY

The objective of the present invention is to provide a MOSFET device and a manufacturing method therefor, which can avoid the damage to the surface of a P-well channel by ion implantation to achieve high conductivity of the device.

In order to achieve the above objective, the present invention provides a manufacturing method of a MOSFET device, including the following steps:
providing a substrate, and implanting first well ions of a first conductive type into a surface layer on the front of the substrate to form a first implantation region;
implanting second well ions of a first conductive type into the substrate below the first implantation region to form a second implantation region;
implanting source ions of a second conductive type into a surface layer of the first implantation region to form a source region;
activating the first well ions in the first implantation region so that the junction of the first implantation region horizontally diffuses to the required width and is longitudinally connected to the second implantation region, so as to form a required well region; and
forming a gate oxide layer and a gate which are stacked in sequence on the front of the substrate, and using a region where the first implantation region is in contact with the gate oxide layer as a channel of the MOSFET device.

Optionally, before implanting the first well ions into the surface layer on the front of the substrate, the manufacturing method further includes: forming a patterned mask layer for defining a well region on the front of the substrate; and then, using the patterned mask layer as a mask, and implanting the first well ions, the second well ions and the source ions into the substrate in sequence.

Optionally, after forming the source region and before activating the first well ions in the first implantation region, the manufacturing method further includes:
removing the patterned mask layer; and
implanting bulk ions of the first conductive type in a portion of the source region to form a bulk region, and enabling the bulk region to penetrate into a portion of the first implantation region to short-circuit the source region and the first implantation region.

Optionally, the first well ions include boron ions or boron fluoride ions; and the second well ions include aluminum ions.

Optionally, implantation process parameters of the first well ions are as follows: the implantation energy is 50-300 keV, and the implantation dose is 1E11/cm²-6E14/cm².

Optionally, the first well ions in the first implantation region are activated by an annealing process, the annealing temperature is 1500-1900° C., and the annealing time is 2-200 min.

Optionally, the substrate includes a silicon carbide layer of the second conductive type, and both the first implantation region and the second implantation region are formed in the SiC layer.

Optionally, the manufacturing method further includes:
forming an interlayer dielectric layer on the front of the substrate, the interlayer dielectric layer burying the gate inside and exposing a portion of the source region;
forming a source metal layer on the interlayer dielectric layer, the source metal layer being electrically connected to the source region; and
forming a drain metal layer on the back of the substrate.

Based on the same inventive concept, the present invention further provides a MOSFET device, including:
a substrate;
a well region of a first conductive type, where the well region includes a first implantation region and a second implantation region which are formed from top to bottom, the first implantation region is formed in a surface layer of a portion of the region on the front of the substrate, the second implantation region is formed in the substrate below the bottom of the first implantation region, and the first implantation region longitudinally diffuses to be connected to the second implantation region;
a source region formed on a surface layer of the first implantation region; and
a gate oxide layer and a gate which are stacked on the front of the substrate in sequence, where the gate is in contact with both the first implantation region and the source region, and the first implantation region horizontally extends further compared to the second implantation region at the bottom of the gate.

Optionally, the substrate includes a SiC layer of a second conductive type, and both the first implantation region and the second implantation region are formed in the SiC layer; ions of the first conductive type doped in the first implantation region include boron ions or boron fluoride ions; and ions of the first conductive type doped in the second implantation region include aluminum ions.

Compared with the prior art, the technical solution of the present invention at least has one of the following beneficial effects:
1. First, a first implantation region easy to diffuse is formed, and then, a second implantation region which is not easy to diffuse and has a deeper junction is formed in sequence. After ion implantation in a source region and the like is completed, the first implantation region is activated to form a required well region in a mode of junction diffusion in the first implantation region, and the second implantation region is used for increasing the depth of the well region, thereby avoiding the problems of damage to the surface of a substrate at a channel caused by the formation of a P well directly through multiple Al ion implantation in the prior art, which leads to the roughness of the surface of the channel of the device, and achieves high conductivity of the device.
2. The ion implantation in the first implantation region, the second implantation region and the source region can use a same mask layer, so that the process is simple to implement, and the photoetching frequency can be effectively reduced.

### BRIEF DESCRIPTION OF THE DRAWINGS

Those skilled in the art will understand that the accompanying drawings are provided for better understanding the present invention without any limitation on the scope of the present invention.

FIG. 1 shows a schematic flowchart illustrating a manufacturing method of a MOSFET device according to an embodiment of the present invention.

FIG. 2 shows cross-sectional schematic views illustrating device structures in the manufacturing method of the MOSFET device shown in FIG. 1.

### DETAILED DESCRIPTION

In the following description, a lot of specific details are given in order to provide a more thorough understanding of the present invention. However, it is obvious to those skilled in the art that the present invention may be implemented without one or more of these details. In other examples, in order to avoid confusion with the present invention, some technical features known in the art are not described. It should be understood that the present invention may be implemented in different forms and should not be limited to the embodiments provided here. On the contrary, the embodiments are provided to make the disclosure more thorough and complete, and fully convey the scope of the present invention to those skilled in the art. In the accompanying drawings, the sizes of layers and regions and the relative sizes may be exaggerated for clarity. Throughout the specification, same reference numerals represent same components. It should be understood that when a component or layer is referred to as being “on” or “connected to” another component or layer, the component may be directly on the another component or layer or connected to the another component or layer, or there may be an intervening component or layer. On the contrary, when a component is referred to as being “directly on” or “directly connected to” another component or layer, there is no intervening component or layer. Although terms such as “first” and “second” may be used for describing various components, elements, regions, layers and/or parts, the components, elements, regions, layers, and/or parts should not be limited by the terms. The terms are only used for distinguishing one component, element, region, layer or part from another component, element, region, layer or part. Therefore, without departing from the instruction of the present invention, a first component, element, region, layer or part discussed below may be represented as a second component, element, region, layer or part. Spatial relationship terms such as “below”, “under”, “lower”, “above”, “on” and “upper” can be used here for convenience of describing the relationship between a component or feature shown in the figure and another component or feature. It should be understood that in addition to the orientations shown in the figure, the spatial relationship terms are also intended to include different orientations of devices in use and operation. For example, if a device in the figure is turned, the component or feature described as “below”, “under” or “being on the lower part” will be oriented as being “above” another component or feature. The device may be oriented by rotating 90 degrees or in other orientations, and the spatial description terms used here are explained accordingly. The terms are only used for describing specific embodiments here and are not intended to limit the present invention. Singular forms including “a”, “an” and “the/this” used here may also be intended to include plural forms, unless the context clearly indicates another mode. It should also be understood that the term “include” is used for determining the presence of features, steps, operations, components and/or elements, but does not exclude the presence or addition of one or more other features, steps, operations, components, elements and/or groups. The term “and/or” used here includes any or all combinations of related listed items.

The technical solution provided by the present invention is further described in detail below with reference to the accompanying drawings and specific embodiments. According to the following descriptions, the advantages and features of the present invention will be clearer. It should be noted that the accompanying drawings are drawn in an extremely simplified form and imprecise proportion, which are only used for conveniently and clearly assisting in describing the objectives of the embodiments of the present invention.

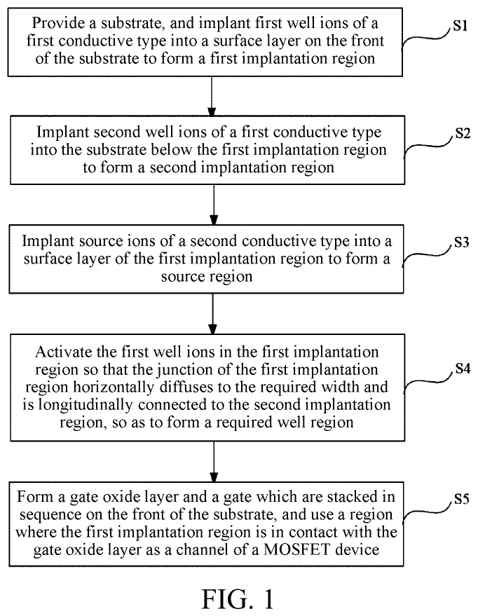

Referring to FIG. 1, an embodiment of the present invention provides a manufacturing method of a MOSFET device, including the following steps:
S1: a substrate is provided, and first well ions of a first conductive type (such as a P type) are implanted in a surface layer on the front of the substrate to form a first implantation region;
S2: second well ions of the first conductive type are implanted in the substrate below the first implantation region to form a second implantation region;
S3: source ions of a second conductive type (such as an N type) are implanted in a surface layer of the first implantation region to form a source region;
S4: the first well ions in the first implantation region are activated so that the junction of the first implantation region horizontally diffuses to the required width and is longitudinally connected to the second implantation region, so as to form a required well region; and
S5: a gate oxide layer and a gate which are stacked in sequence are formed on the front of the substrate, and a region where the first implantation region is in contact with the gate oxide layer is used as a channel of the MOSFET device.

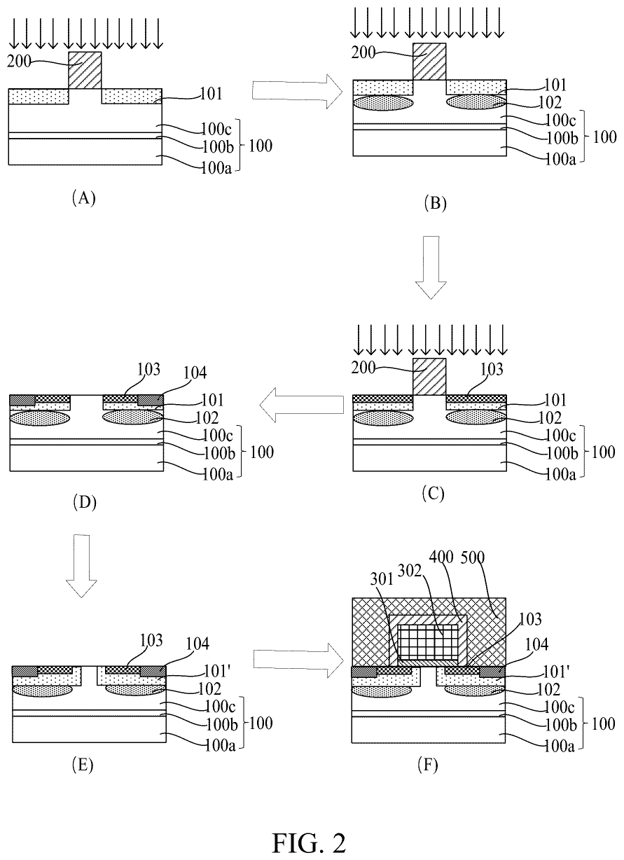

Referring to FIG. 2 (A), in step S1, any appropriate semiconductor material such as silicon carbide (SiC) or silicon may be provided to form a substrate 100. For example, the provided substrate 100 is an N type SiC substrate with three layers from bottom to top, namely an N+substrate 100a, a buffer layer 100b and an N-drift layer 100c in sequence. The doping concentration of N type ions in the N-drift layer 100c is lower than the doping concentration of N type ions in the N+substrate 100a.

Specifically, referring to FIG. 2 (A), in step S1, first, the surface of the substrate 100 may be cleaned and dried; and then, a mask layer material is deposited on the N-drift layer 100c, the mask layer material may be selected from one or more of polysilicon (poly Si), single crystal silicon (Si), silicon dioxide (SiO₂), silicon nitride (SiN) and the like, the mask layer material may be a single layer film or may be formed by superposition of films of multiple different materials, and the mask layer material is subjected to photoetching and etching to form a patterned mask layer 200 for defining the P well to be formed. In this example, implantation windows (not shown) for the P well to be formed are defined on both sides of the patterned mask layer 200; and then, the patterned mask layer 200 is used as a mask, and first well ions of P type are implanted into a surface layer of the N-drift layer 100c to form a first implantation region 101 in the surface layer of the N-drift layer 100c on both sides of the patterned mask layer 200. The first well ions used in this step are ions that may form a cavity in the N-drift layer 100c and are easier to diffuse at a high temperature compared to subsequent second well ions and source ions. As an example, the first well ions are boron ions or boron fluoride ions, the implantation direction may be perpendicular to the surface of the N-drift layer 100c, the implantation energy is 50-300 keV (such as 100 keV, or 200 keV), and the implantation dose is 1E11/cm²-6E14/cm² (such as 5E12/cm², or 1E13/cm²).

Referring to FIG. 2 (B), in step S2, the patterned mask layer 200 is used as a mask, and second well ions of P type are implanted in the N-drift layer 100c below the first implantation region 101 to form a second implantation region 102 in the N-drift layer 100c below the first implantation region 101 on both sides of the patterned mask layer 200. Therefore, the second implantation region 102 may form a deeper junction than the first implantation region 101. As an example, ions may be vertically or obliquely implanted in the N-drift layer 100c below the first implantation region 101 through multiple aluminum (Al) ion implantation according to the depth and width requirements for P well design. The implantation temperature is 400-1000° C. (such as 500° C., or 800° C.), the implantation energy is 200-500 keV (such as 300 keV, or 400 keV), and the implantation dose is 1E11/cm²-6E14/cm² (such as 5E12/cm², 1E13/cm², or 1E14/cm²).

Referring to FIG. 2 (C), in step S3, the patterned mask layer 200 is used as a mask, and N type source ions are vertically or obliquely implantation in the surface layer of the first implantation region 101 according to the depth and width requirements for source region design, so as to form a source region 103 in the surface layer of the first implantation region 101 on both sides of the patterned mask layer 200. As an example, N type source ions include at least one of phosphorus (P) ions, arsenic (As) ions, nitrogen (N) ions and the like, the implantation energy is 50-300 keV (such as 100 keV, or 200 keV), and the implantation dose is 1E14/cm²-1E16/cm² (such as 5E14/cm², 1E15/cm², or 5E15/cm²).

Referring to FIG. 2 (D), in step S3, optionally, after the source region 103 is formed, the patterned mask layer 200 is removed, bulk ions of P type are implantation in a portion of the source region 103 to form a bulk region 104 (also known as a contact region), the bottom of the bulk region 104 penetrates into a portion of the first implantation region 101 to short-circuit the source region 103 and the first implantation region 101, and the doping concentration of the P type ions is higher than that in the first implantation region 101. As an example, the bulk ions may include at least one of boron ions, boron fluoride ions and aluminum ions, the implantation energy is 50-300 keV (such as 100 keV, or 200 keV), and the implantation dose is 1E14/cm²-1E16/cm² (such as 5E14/cm², 1E15/cm², or 5E15/cm²).

Referring to FIG. 2 (E), in step S4, the substrate 100 is annealed by a high-temperature annealing process to activate the first well ions in the first implantation region 101, and also activate the second well ions in the second implantation region 102, and the P type ions of the N-type ion bulk region 104 in the source region 103. The annealing temperature is 1500-1900° C. (such as 1650° C., 1700° C., or 1800° C.), and the annealing time is 2-200 min (such as 10 min, 20 min, 50 min, or 100 min). The high-temperature annealing process causes diffusion of first well ions such as boron ions in the first implantation region 101, the bottom of the first implantation region 101′ after diffusion is longitudinally connected to the top of the second implantation region 102, and the first implantation region after diffusion horizontally extends to a required width of the P well to provide a required channel width subsequently. Moreover, the diffusion of the second well ions in the second implantation region 102, and the P type ions of the N-type ion bulk region 104 in the source region 103 is relatively weak compared to the first well ions in the first implantation region 101, and the N-drift layer 101c between the two first implantation regions 101′ after diffusion is used as a depletion region.

In this step, the required well region is composed of the first implantation region 101′ at the upper part after diffusion and the second implantation region 102 at the lower part. Moreover, since the required channel is formed by diffusion of the first implantation region 101, the roughness of the surface of the channel can be greatly reduced. As a result, the interface scattering of channel electrons in the finally manufactured MOSFET device can be reduced, thereby increasing the channel mobility.

Referring to FIG. 2 (F), in step S5, first, an appropriate gate oxidation process such as a thermal oxidation process or a chemical vapor deposition process may be used for forming a gate oxide layer 301 on the front of the bulk region 104, the source region 103, the first implantation region 101′ after diffusion and the N-drift layer 100c; and then, a gate material layer may be deposited on the surface of the gate oxide layer 301, and the deposited gate material layer and the gate oxide layer 301 are subjected to photoetching and etching to form a gate 302. The formed gate 302 is overlapped with both the first implantation region 101′ after diffusion and the source region 104, and a region where the first implantation region 101′ after diffusion is in contact with the gate oxide layer 301 is used as a channel of the MOSFET device.

In this step, since the P well is formed in a mode of diffusion in step S4, the roughness of the surface of the channel can be effectively avoided, and the SiC crystal quality of the N-drift layer 100c used as a depletion region can be ensured to be intact. As a result, the quality of the formed gate oxide layer 301 can be ensured, and the defect density of the channel can be reduced, thereby further improving the temperature drift performance of the device and further enhancing the reliability of the device.

Further optionally, after the gate 302 is formed, first, the front of the substrate 100 is covered with an interlayer dielectric layer 400 by a chemical vapor deposition process and the like. The interlayer dielectric layer 400 may be a single-layer dielectric film structure or a structure formed by stacking multiple layers of dielectric films. Then, the interlayer dielectric layer 400 is subjected to photoetching and etching to pattern the interlayer dielectric layer 400, and the patterned interlayer dielectric layer 400 may bury the gate 302 inside and expose a portion of the source region 103. Then, a source metal layer 500 (such as a metal material or alloy of copper, aluminum, gold, and the like) is formed on the interlayer dielectric layer 400 by an appropriate process such as metal sputtering deposition or vapor deposition. The source metal layer 500 is electrically connected to both the source region 103 and the bulk region 104. Then, a drain metal layer (not shown) is formed on the back of the N+substrate 100a.

According to the manufacturing method of the MOSFET device in this embodiment, the required well region is formed in a mode of diffusion. On one hand, the roughness of the surface of the channel can be greatly reduced, and the interface scattering of channel electrons can be reduced, thereby increasing the channel mobility. On the other hand, the defect level of the channel and the quality of the gate oxide layer can be improved, thereby further improving the temperature drift performance of the device and further enhancing the reliability of the device.

In addition, the ion implantation in the first implantation region, the second implantation region and the source region can be implemented by the same patterned mask layer 200, so that the process is simple to implement, and the photoetching frequency can be effectively reduced.

Referring to FIG. 2 (F), an embodiment of the present invention further provides a MOSFET device which is preferably manufactured by the manufacturing method of the MOSFET device of the present invention. The MOSFET device includes:
a substrate 100, where the substrate 100 may be any appropriate semiconductor material, for example, the substrate 100 may be an N type SiC substrate with three layers from bottom to top, namely an N+substrate 100a, a buffer layer 100b and an N-drift layer 100c in sequence;
a first conductive type (such as a P type) of well region, including a first implantation region 101 and a second implantation region 102 which are formed from top to bottom, where the first implantation region 101 is formed in a surface layer of a portion of the region on the front of the N-drift layer 100c, the second implantation region 102 is formed in the N-drift layer 100c below the bottom of the first implantation region 101, the first implantation region 101 longitudinally diffuses to be connected to the second implantation region 102, ions of the first conductive type doped in the first implantation region 101 include boron ions or boron fluoride ions, and ions of the first conductive type doped in the second implantation region 102 include aluminum ions;
a source region 103 formed on a surface layer of the first implantation region 101; and
a gate oxide layer 301 and a gate 302 which are stacked on the front of the N-drift layer 100c in sequence, where the gate 302 is overlapped with both the first implantation region 103 and the source region 104, and the first implantation region 103 horizontally extends further compared to the second implantation region 102 at the bottom of the gate 302.

In conclusion, according to the MOSFET device and the manufacturing method therefor of the present invention, first, a first implantation region easy to diffuse is formed, and then, a second implantation region which is not easy to diffuse and has a deeper junction is formed in sequence. After ion implantation in a source region and the like is completed, the first implantation region is activated to form a required well region in a mode of junction diffusion in the first implantation region, and the second implantation region is used for increasing the depth of the well region, thereby avoiding the problems of damage to the surface of a substrate at a channel and roughness of the surface of the channel of the device caused by the formation of a P well directly through multiple Al ion implantation in the prior art, and achieving high conductivity of the device. In addition, the ion implantation in the first implantation region, the second implantation region and the source region can use a same mask layer, so that the process is simple to implement, and the photoetching frequency can be effectively reduced.

The above description is only a description of the preferred embodiments of the present invention and does not limit the scope of the present invention. Any changes or modifications made by those skilled in the art of the present invention according to the above disclosed contents belong to the protection scope of the technical solution of the present invention.

1. A manufacturing method of a metal oxide semiconductor field effect transistor (MOSFET) device, comprising:
providing a substrate, and implanting first well ions of a first conductive type into a surface layer on the front of the substrate to form a first implantation region;
implanting second well ions of a first conductive type into the substrate below the first implantation region to form a second implantation region;
implanting source ions of a second conductive type into a surface layer of the first implantation region to form a source region;
activating the first well ions in the first implantation region so that the junction of the first implantation region horizontally diffuses to the required width and is longitudinally connected to the second implantation region, so as to form a required well region; and
forming a gate oxide layer and a gate which are stacked in sequence on the front of the substrate, and using a region where the first implantation region is in contact with the gate oxide layer as a channel of the MOSFET device.

2. The manufacturing method according to claim 1, wherein before implanting the first well ions into the surface layer on the front of the substrate, the manufacturing method further comprises:
forming a patterned mask layer for defining a well region on the front of the substrate; and
using the patterned mask layer as a mask, and implanting the first well ions, the second well ions and the source ions into the substrate in sequence.

3. The manufacturing method according to claim 2, wherein after forming the source region and before activating the first well ions in the first implantation region, the manufacturing method further comprises:
removing the patterned mask layer; and
implanting bulk ions of the first conductive type in a portion of the source region to form a bulk region, and enabling the bulk region to penetrate into a portion of the first implantation region to short-circuit the source region and the first implantation region.

4. The manufacturing method according to claim 1, wherein the first well ions comprise boron ions or boron fluoride ions; and the second well ions comprise aluminum ions.

5. The manufacturing method according to claim 4, wherein implantation process parameters of the first well ions are as follows: the implantation energy is 50-300 keV, and the implantation dose is 1E11/cm²-6E14/cm².

6. The manufacturing method according to claim 4, wherein the first well ions in the first implantation region are activated by an annealing process, the annealing temperature is 1500-1900° C., and the annealing time is 2-200 min.

7. The manufacturing method according to claim 4, wherein the substrate comprises a silicon carbide layer of the second conductive type, and both the first implantation region and the second implantation region are formed in the SiC layer.

8. The manufacturing method according to claim 1, further comprising:
forming an interlayer dielectric layer on the front of the substrate, the interlayer dielectric layer burying the gate inside and exposing a portion of the source region;
forming a source metal layer on the interlayer dielectric layer, the source metal layer being electrically connected to the source region; and
forming a drain metal layer on the back of the substrate.

9. A MOSFET device, comprising:
a substrate;
a well region of a first conductive type, wherein the well region comprises a first implantation region and a second implantation region which are formed from top to bottom, the first implantation region is formed in a surface layer of a portion of the region on the front of the substrate, the second implantation region is formed in the substrate below the bottom of the first implantation region, and the first implantation region is longitudinally connected to the second implantation region;
a source region formed on a surface layer of the first implantation region; and
a gate oxide layer and a gate which are stacked on the front of the substrate in sequence, wherein the gate is in contact with both the first implantation region and the source region, and the first implantation region horizontally extends further compared to the second implantation region at the bottom of the gate.

10. The MOSFET device according to claim 9, wherein the substrate comprises a SiC layer of a second conductive type, and both the first implantation region and the second implantation region are formed in the SiC layer; first well ions of the first conductive type doped in the first implantation region comprise boron ions or boron fluoride ions; and second well ions of the first conductive type doped in the second implantation region comprise aluminum ions.
